(19) United States
(12) Patent Application Publication
(10) Pub. No.: US 2024/0355855 A1
(43) Pub. Date: Oct. 24, 2024

(54) DEEP TRENCH ISOLATION STRUCTURE FOR IMAGE SENSOR NARROWED BY EPITAXY GROWTH

(71) Applicant: Taiwan Semiconductor Manufacturing Company, Ltd., Hsinchu (TW)

(72) Inventors: Yu-Hung Cheng, Tainan City (TW); Szu-Yu Wang, Hsinchu City (TW); Ching I Li, Tainan (TW)

(21) Appl. No.: 18/354,217

(22) Filed: Jul. 18, 2023

Related U.S. Application Data
(60) Provisional application No. 63/497,498, filed on Apr. 21, 2023.

(51) Int. Cl. H01L 27/146

(52) U.S. Cl. CPC H01L 27/1463; H01L 27/14689; H01L 27/1464

(57) ABSTRACT

The problem of forming a deep trench isolation (DTI) structure suitable for photodetectors having a narrow pitch is solved by a process in which a p-doped epitaxial layer is grown on the sidewalls of trenches formed by etching. The epitaxial layer becomes part of the active region of any adjacent photodetectors and narrows the DTI structure that is formed by dielectric in the trenches. The epitaxial layer may be allowed to close the trench mouths and to grow on the front side. Floating diffusion regions and the like may then be formed directly over the DTI structure. Optionally, dislocations in the epitaxial layer are removed by laser annealing. Optionally the epitaxial layer is planarized after annealing. The trenches may be accessed from the back side by thinning the substrate, whereupon the trenches may be partially or completely filled with dielectric to form the DTI structure.

### REFERENCE TO RELATED APPLICATION

This Application claims the benefit of U.S. Provisional Application No. 63/497,498, filed on Apr. 21, 2023, the contents of which are incorporated herein by reference in their entirety.

### BACKGROUND

Integrated circuits (ICs) comprising image sensors are used in a wide range of modern-day electronic devices such as cameras and cell phones. Complementary metal-oxide semiconductor (CMOS) image sensors (CISs) have become popular. Compared to charge-coupled devices (CCDs), CISs are increasingly favored due to low power consumption, small pixel size, fast data processing, and low manufacturing cost. As the pixel sizes are made smaller, manufacturing becomes increasingly difficult as does limiting crosstalk between pixels. These are ongoing challenges where unique solutions can provide improved performance.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1A illustrates a cross-sectional view of an image sensing device according to some embodiments.

FIG. 1B provides an expanded view of the area 1B of FIG. 1A.

FIG. 1C illustrates a plan view taken along the line C-C′ of FIG. 1A.

FIG. 2A illustrates a cross-sectional view of an image sensing device according to some other embodiments.

FIG. 2B provides an expanded view of the area 2B of FIG. 2A.

FIG. 3 illustrates a cross-sectional view of an image sensing device according to some other embodiments.

FIG. 4A illustrates a cross-sectional view of an image sensing device according to some other embodiments.

FIG. 4B provides an expanded view of the area 4B of FIG. 4A.

FIG. 5 illustrates a cross-sectional view of an image sensing device according to some other embodiments.

FIG. 6 illustrates a cross-sectional view of an image sensing device according to some other embodiments.

FIG. 7-22 illustrate a series of cross-sectional views exemplifying a method of forming an image sensing device according to some other embodiments.

FIG. 23-26 illustrate variations of the method of FIG. 7-22 according to various other embodiments.

FIG. 27 provides a flow chart illustrating some embodiments of a method of forming an image sensing device.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

Some CISs are designed for back side illumination (BSI) and include an array of photodetectors within a semiconductor substrate. The photodetectors may be separated by a deep trench isolation (DTI) structure. The DTI structure may be a back side deep trench isolation (BDTI) structure, which is an isolation structure in which the trenches are formed in the back side of the semiconductor substrate and tend to become narrower from back to front, or a front side deep trench isolation (FDTI) structure, which is a DTI structure in which the trenches are formed in the front side of the semiconductor substrate and tend to become narrower from front to back. The DTI structure may be in the form of a grid having segments between adjacent photodetectors.

As the photodetector pitch is made smaller, the DTI structure takes up a progressively larger proportion of the image sensing area. To counteract that tendency, it is desirable to make the DTI structure narrower. Attempts to make the DTI structure narrower are hampered by the limitation on aspect ratio inherent in the process of etching the trenches. In addition, as the trenches are made narrower, they become more susceptible to pinching off during backfill. Pinching off during backfill can interfere with passivating defects on the trench sidewalls.

In accordance with some aspects of the present disclosure, the problem of forming a DTI structure suitable for photodetectors with small pitch is solved by a process in which a layer of p-doped semiconductor is grown epitaxially on the sidewalls of trenches formed in the semiconductor substrate by etching. The epitaxial layer becomes part of the semiconductor body and the active region of any adjacent photodetectors. The epitaxial layer makes the trenches, and thus the DTI structure formed within the trenches, narrower than the trenches as etched. Any defects on the sidewalls of the trenches as etched are passivated by the p-type doping. The p-type epitaxial layer also contributes to electrical isolation between adjacent pixels. In some embodiments, the epitaxial layer is grounded. In some embodiments, the epitaxial layer is coupled to a bias source through which a bias voltage may be applied to the epitaxial layer. In some embodiments, the DTI structure is an FDTI structure. The FDTI structure is formed before any front end of line (FEOL) structures that might be adversely affected by the process conditions of epitaxial growth.

The epitaxial growth process may continue until the trench mouths are closed. Depending on the epitaxial growth process conditions, dislocations may form near the trench mouths where the sidewalls of the trenches begin to merge. In some embodiments, these dislocations are eliminated or ameliorated by annealing. In some embodiments, the heat for annealing is provided by laser pulses. Annealing may increase surface roughness. In some embodiments, chemical mechanical polishing (CMP) or the like is applied to reduce the surface roughness.

In some embodiments, the epitaxial layer is formed by a non-selective growth process so that the p-doped epitaxial layer extends onto the front side of the semiconductor substrate. In some embodiments, that front side epitaxial layer is incorporated into the photodetector structures. In some embodiment, a floating diffusion region with n-type doping is formed in the p-doped front side epitaxial layer. In some embodiments, the p-doped front side epitaxial layer provides a channel for a transfer gate. In some embodiments, the transfer gate is a vertical transfer gate that includes an electrode that extends through the p-doped front side epitaxial layer.

In some embodiments, after forming the FDTI structure and the photodetectors the semiconductor substrate undergoes back end of line (BEOL) process that forms a metal interconnect structure on the front side. A bonding layer may be formed on the metal interconnect structure through which the semiconductor substrate may be bonded to a second substrate. The semiconductor substrate may then be thinned from the back side. In some embodiments, the thinning process opens the trenches from the back side and dielectric is deposited into the trenches from the back side. The dielectric provides the DTI structure. In some embodiments, the dielectric fills the trenches. In some embodiments, depositing the dielectric from the back side seals off the trenches while leaving void areas within the trenches.

Some aspects of the present disclosure relate to an image sensing device of the type that may be made by the foregoing process. The image sensing device includes a semiconductor substrate having a photodetector array. The semiconductor substrate has sidewalls defining trenches between adjacent photodetectors in the array. The trenches contain the dielectric of a DTI structure. The sidewalls are provided by an epitaxial layer of p-doped semiconductor. In some embodiments, the trenches narrow as they approach the front side of the semiconductor substrate, narrow as they approach the back side of the semiconductor substrate and are widest between their tops and their bottoms. The trenches may narrow as they approach the back side due to the narrowing of original trenches that were etched into the semiconductor substrate from the front side. The trenches may narrow as they approach the front side due to the epitaxial layer forming more thickly nearer the front side. The trenches are narrower than trenches that were formed by etching. In some embodiments, the trenches having the sidewalls provided by the epitaxial layer have an aspect ratio of about 50:1 or greater.

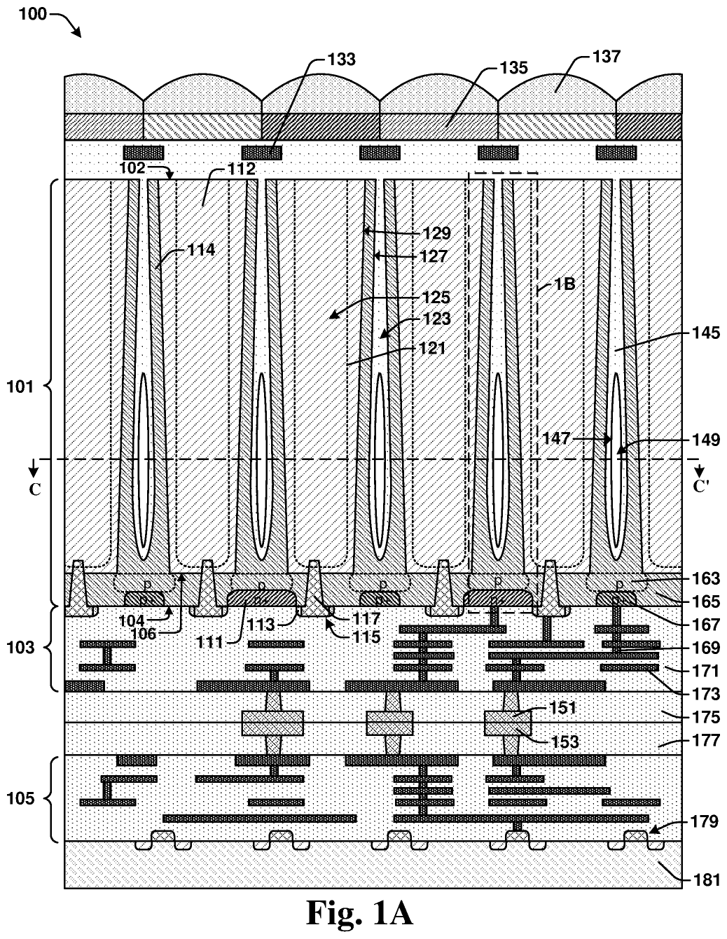

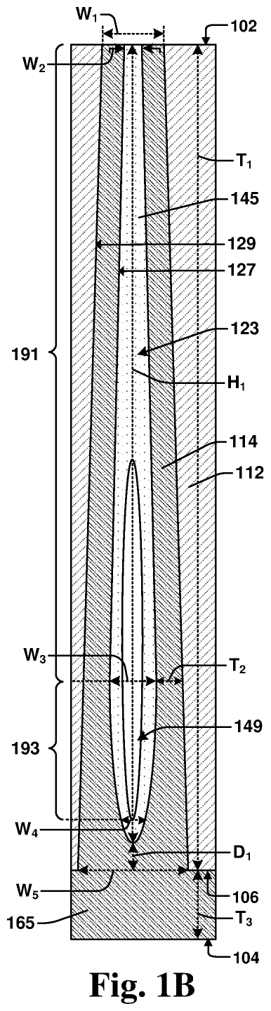

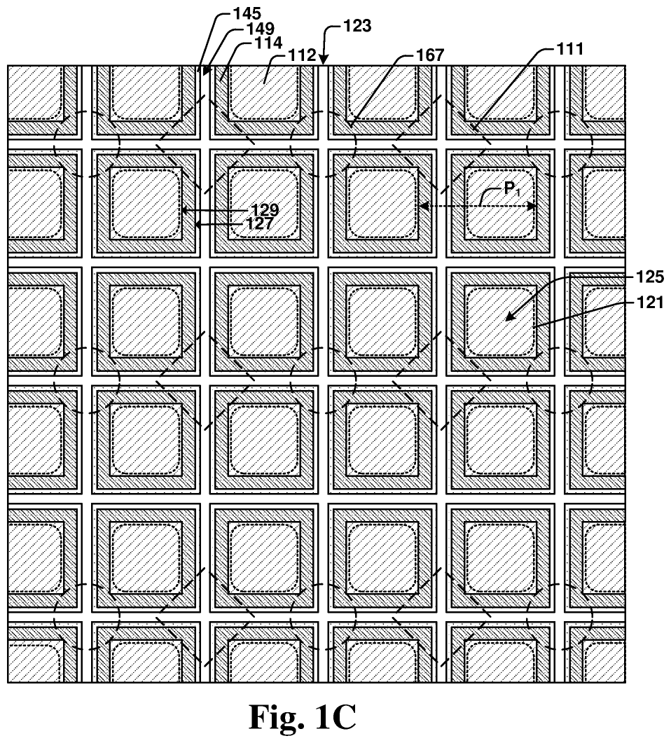

FIG. 1A illustrates a cross-sectional view of an image sensing device 100 according to some embodiments. The image sensing device 100 includes an array of photodetectors 125 in a semiconductor body 101. The semiconductor body 101 has a front side 104, a back side 102, and is a composite of a bulk semiconductor 112 and an epitaxial layer 114 of p-doped semiconductor. The epitaxial layer 114 extends into trenches defined by sidewalls 129 of the bulk semiconductor 112. A DTI structure 123 is disposed between the sidewalls 127 provided by the epitaxial layer 114. The DTI structure 123 includes an isolation dielectric 145 and may have voids 149. The voids 149 may have sidewalls 147 provided by the isolation dielectric 145.

The isolation dielectric 145 may continue onto the back side 102. On the back side 102, the isolation dielectric 145 may provide an antireflective coating. Alternatively, an antireflective coating may be provided as a separate layer. Microlenses 137 may be positioned to focus incoming light on the photodetectors 125. Color filter 135 may be positioned between the microlenses 137 and the isolation dielectric 145.

The photodetectors 125 comprise image sensing elements such as photodiodes 121. Various n-type and p-type dopant implantation processes may have been conducted to provide the regions of n-type doping and p-type doping that make up the photodiodes 121. Regardless, in some embodiments the photodiodes 121 comprises a PN junction formed between the epitaxial layer 114 and an adjacent area of the bulk semiconductor 112 that has n-type doping.

A front side metal interconnect structure 103 may be disposed on the front side 104 of the semiconductor body 101. The front side metal interconnect structure 103 may comprise wires 173 arranged in a stack of metallization layers. Wires 173 in adjacent metallization layers may be connected by vias 169. The wires 173 and the vias 169 may be surrounded by interlevel dielectric 171.

The image sensing device 100 may be designed for back side illumination. Accordingly, the semiconductor body 101 may be comparatively thin and attached to a second substrate 181 that provides mechanical support. Semiconductor devices 179 may be formed on the second substrate 181 so that the second substrate 181 provides additional functionality. In some embodiments, that additional functionality includes providing logic circuits. In some embodiments, that additional functionality includes providing transistors associated with the photodiode 121. Those transistors may include, for example, select gate, reset gates, or the like.

A second metal interconnect structure 105 may be disposed on the second substrate 181. The semiconductor body 101 and the second substrate 181 may be bonded together through a first bonding layer 175 on the front side metal interconnect structure 103 and a second bonding layer 177 on the second metal interconnect structure 105. Electrical connections between the front side metal interconnect structure 103 and the second metal interconnect structure 105 may be provided by first bond pads 151 in the first bonding layer 175 and second bond pads 153 in the second bonding layer 177.

In some embodiments, the epitaxial layer 114 continues onto a front side 106 of the bulk semiconductor 112 to provide a front side epitaxial layer 165. In some embodiments, floating diffusion regions 111 are provided by heavily n-doped wells disposed within the front side epitaxial layer 165. In some embodiments, transfer gates 115 include vertical gate electrodes 117 that extend through the front side epitaxial layer 165. The floating diffusion regions 111 may have doping in alignment with spacers 113 that are adjacent the vertical gate electrodes 117.

The DTI structure 123 together with the epitaxial layer 114 provides isolation between adjacent photodetectors 125. In some embodiments, that isolation is enhanced by grounding the epitaxial layer 114 or applying a bias voltage to the epitaxial layer 114. The epitaxial layer 114 may be connected to ground or a bias voltage source (not shown) through the front side metal interconnect structure 103. In some embodiments, heavily p-doped contact regions 167 are formed in the front side 104 to facilitate making this connection.

FIG. 1B is an expanded view of the area 1B in FIG. 1A focusing on the structure of the semiconductor body 101 and the DTI structure 123. The DTI structure 123 is bounded by the sidewalls 127 of the epitaxial layer 114. The epitaxial layer 114 is disposed within trenches defined by the sidewalls 129 of the bulk semiconductor 112. The trenches defined by the sidewalls 129 have a width W₅ at the front side 106 of the bulk semiconductor 112. In some embodiments, the width W₅ is in the range from about 120 nm to about 300 nm. In some embodiments, the width W₅ is in the range from about 160 nm to about 200 nm. In some embodiments, the trenches defined by the sidewalls 129 decrease in width from the width W₅ at the front side 106 of the bulk semiconductor 112 to a width W₁ at the back side 102. The width decreases due to a process of etching a trench in the bulk semiconductor 112 from the front side 106. In some embodiments, the width W₁ is from about 10 percent to about 80 percent of the width W₅. In some embodiments, the width W₁ is from about 20 percent to about 60 percent of the width W₅.

The DTI structure 123 has a maximum width W₃ that occurs at an intermediate position between the front side 106 of the bulk semiconductor 112 and the back side 102. In some embodiments, the width W₃ is about 100 nm or less. In some embodiments, the width W₃ is about 60 nm or less. In some embodiments, the width W₃ is in the range from about 30 nm to about 50 nm. These widths pertain to the DTI structure 123 being sufficiently narrow to maintain a large full well capacity and being sufficiently wide to inhibit crosstalk.

In a first zone 191 that is proximate the back side 102 and is above the intermediate position where the maximum width W₃ occurs, the epitaxial layer 114 has a thickness T₂ that is approximately constant. To the extent the thickness T₂ varies in the first zone 191, it gradually decreases in the direction of the back side 102. In some embodiments, the thickness T₂ is in the range from about 30 nm to about 100 nm. In some embodiments, the thickness T₂ is in the range from about 40 nm to about 60 nm.

The DTI structure 123 decreases in width progressively through the first zone 191 until it reaches a width W₂ at the back side 102. This decrease in width of the DTI structure 123 is related to a decrease in width of the trenches defined by the sidewalls 129 of the bulk semiconductor 112. In some embodiments, the width W₂ at the back side 102 is from about 20 percent to about 80 percent of the maximum width W₃. In some embodiments, the width W₂ at the back side 102 is from about 50 percent to about 70 percent of the maximum width W₃., e.g., about 60 percent.

In a second zone 193 that is proximate the front side 104 and is below the intermediate position where the maximum width W₃ occurs, the DTI structure 123 decreases progressively through a width W₄. The width W₄ may occur at a depth corresponding to the voids 149. In some embodiments, the width decreases through the second zone 193 due to the epitaxial layer 114 becoming thicker as it approaches the front side 106 of the bulk semiconductor 112. In some embodiments, the width W₄ is from about 20 percent to about 80 percent of the maximum width W₃.

The DTI structure 123 terminates a distance D₁ from the front side 106 of the bulk semiconductor 112. The DTI structure 123 has a height H₁ that is less than a thickness T₁ of the bulk semiconductor 112 by the distance D₁. In some embodiments, the height H₁ is in the range from about 1 μm to about 3 μm. In some embodiments, the height H₁ is in the range from about 1.5 μm to about 2 μm. A ratio of the height H₁ to the width W₃ is an aspect ratio of the DTI structure 123. In some embodiments, the aspect ratio is greater than about 30:1. In some embodiments, the aspect ratio is in the range from about 50:1 to about 100:1.

The epitaxial layer 114 continues onto the front side 106 of the bulk semiconductor 112 to provide the front side epitaxial layer 165. In some embodiments, a thickness T₃ of the front side epitaxial layer 165 is in the range from about 50 nm to about 200 nm. In some embodiments, the thickness T₃ is in the range from about 80 nm to about 150 nm. Providing the front side epitaxial layer 165 with a suitable thickness facilitates the formation of devices relates to the photodetectors 125 in the front side epitaxial layer 165.

Having the DTI structure 123 recessed below the front side 106 of the bulk semiconductor 112 by the distance D₁ further facilitates forming semiconductor devices in the front side 104 and in particular facilitates the formation of floating diffusion regions 111 directly beneath the DTI structure 123. In some embodiments, the distance D₁ is in the range from about 30 nm to about 200 nm. In some embodiments, the a distance D₁ is in the range from about 50 nm to about 150 nm.

It is desirable for the combined distance D₁ and thickness T₃ to be sufficiently large to accommodate floating diffusion regions 111 and sufficiently small for dislocations that may have resulted from the epitaxial growth process to have been repaired by a laser annealing process. Accordingly, in some embodiments the combined distance D₁ and thickness T₃ is in the range from about 100 nm to about 300 nm. In some embodiments the combined distance D₁ and thickness T₃ is in the range from about 150 nm to about 220 nm.

FIG. 1C provide a plan view of the image sensing device 100 taken through the line C-C′ of FIG. 1A. As shown in FIG. 1C the DTI structure 123 and the trenches defined by the sidewalls 127 of the epitaxial layer 114 each form a grid with segments that laterally surround and isolate the photodetectors 125. The floating diffusion regions 111, which may be shared by up to four photodetectors 125 are directly over the DTI structure 123 at crossroads between these segments. The heavily p-doped contact regions 167 through which the epitaxial layer 114 may be grounded may also be directly over the DTI structure 123 at crossroads between these segments. The photodetectors 125 form an array that may have a small pitch P₁. In some embodiments, the pitch P₁ is the range from about 0.2 μm to about 0.4 μm. In some embodiments, the pitch P₁ is about 0.3 μm or less. In some embodiments, the pitch P₁ is about 0.25 μm or less.

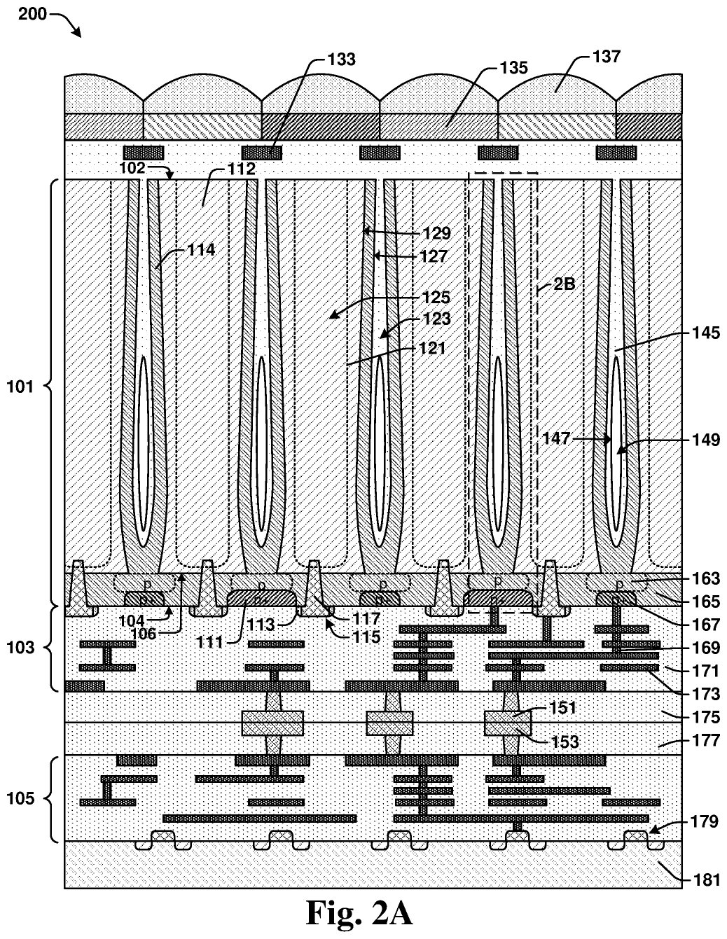

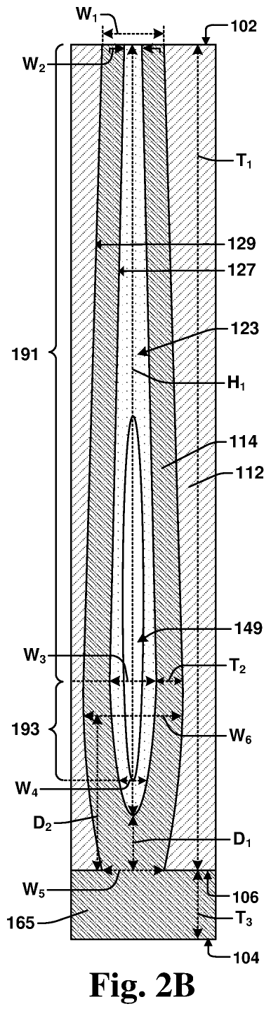

FIG. 2A illustrates a cross-sectional view of an image sensing device 200 according to some other embodiments. FIG. 2B is an expanded view of FIG. 2A focusing on the area 2B. The image sensing device 200 is like the image sensing device 100 of FIG. 1A except that in the image sensing device 200, the trenches defined by the sidewalls 129 of the bulk semiconductor have a maximum width W₆ (see FIG. 2B) a distance D₂ from the front side 106. The trenches that are defined by the sidewalls 129 of the bulk semiconductor 112 become narrower between the point where the maximum width W₆ occurs and the front side 106. This narrowing facilitates causing the epitaxial layer 114 to merge a distance D₁ from the front side 106. Keeping the distance D₁ large facilitate forming floating diffusion regions 111 directly below the DTI structure 123.

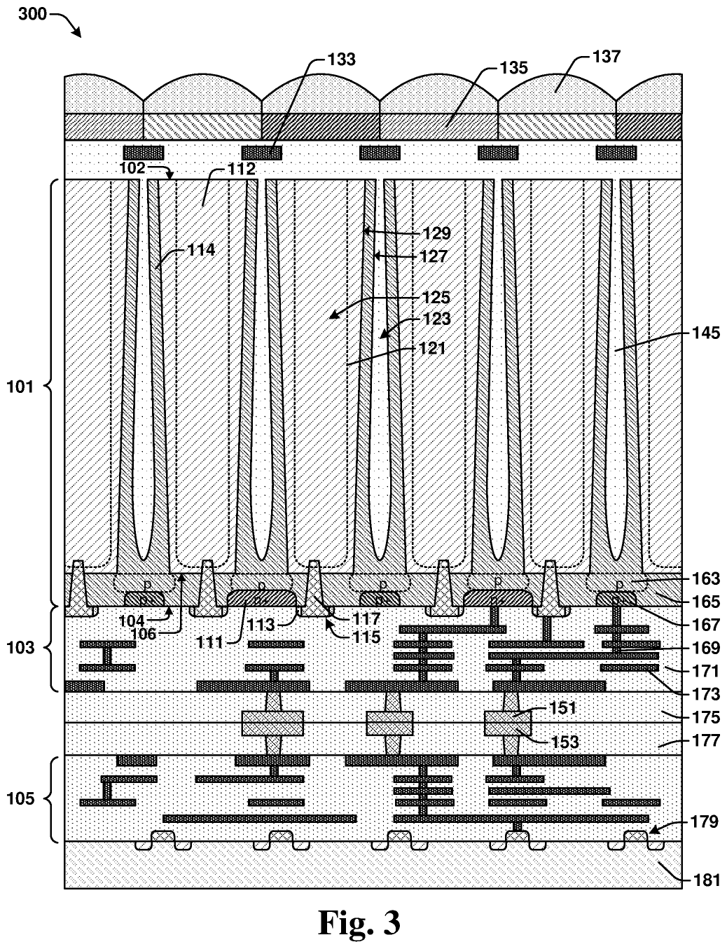

FIG. 3 illustrates a cross-sectional view of an image sensing device 300 according to some other embodiments. The image sensing device 300 is like the image sensing device 100 of FIGS. 1A and 1B except that in the image sensing device 300, the DTI structure 123 lack the void 149 (see FIG. 1A). In the image sensing device 300, the isolation dielectric 145 of the DTI structure 123 fills the trenches defined by the sidewalls 127 of the epitaxial layer 114.

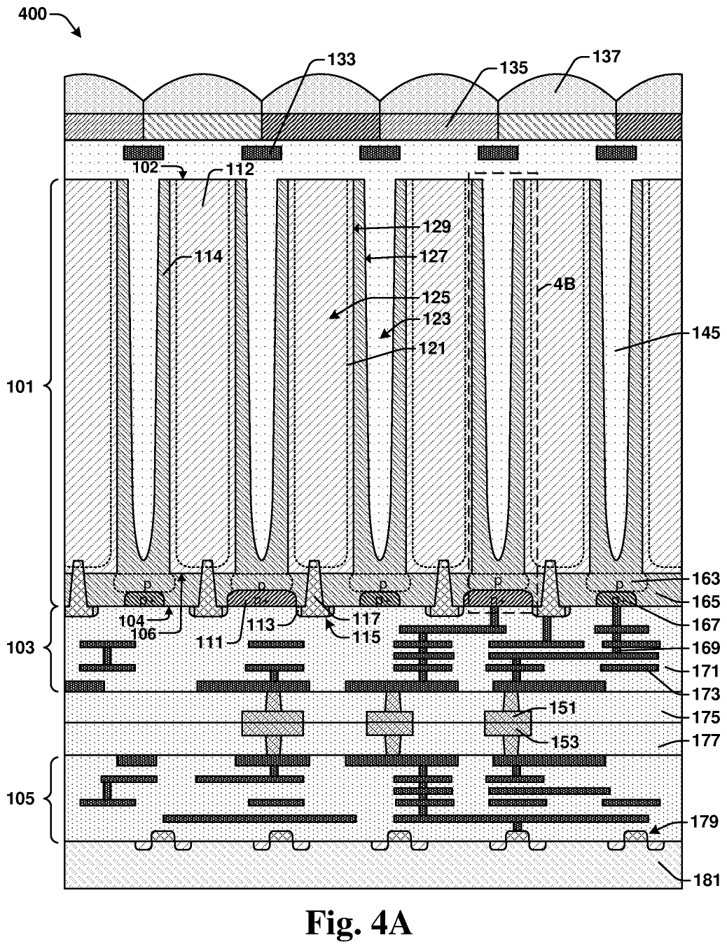

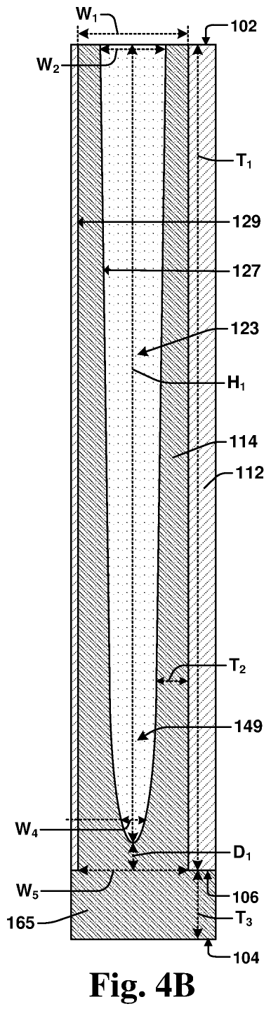

FIG. 4A illustrates a cross-sectional view of an image sensing device 400 according to some other embodiments. FIG. 4B is an expanded view of FIG. 4A focusing on the area 4B. The image sensing device 400 is like the image sensing device 300 of FIG. 3 except that in the image sensing device 400 the trenches defined by the sidewall 129 of the bulk semiconductor 112 have substantially constant width. The DTI structure 123 of the image sensing device 400 does not have a bulge in the middle, but rather has a width that remains constant or increases as the DTI structure 123 approaches the back side 102. This configuration increases the width W₂ of the DTI structure 123 at the back side 102 but makes it easier to form the DTI structure 123 without the void 149 (see FIG. 1A).

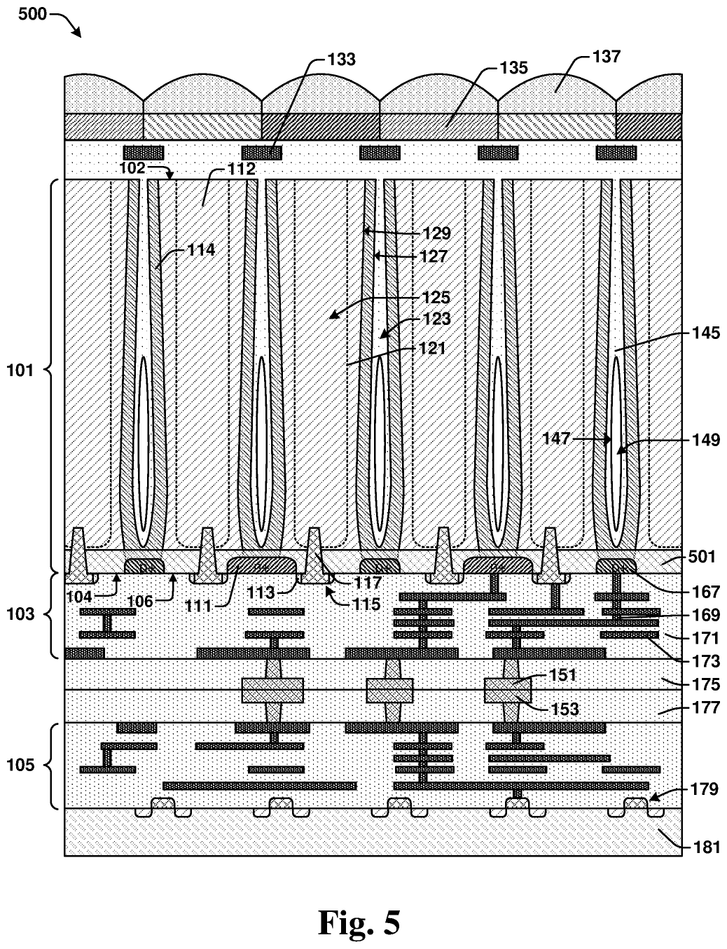

FIG. 5 illustrates a cross-sectional view of an image sensing device 500 according to some other embodiments. The image sensing device 500 is like the image sensing device 200 of FIGS. 2A and 2B in many respects except that in the image sensing device 500 the epitaxial layer 114 does not extend onto the front side 106 of the bulk semiconductor 112. A p-doped layer 501 on the front side 104 may provide the functionality of the front side epitaxial layer 165 (see FIG. 2A).

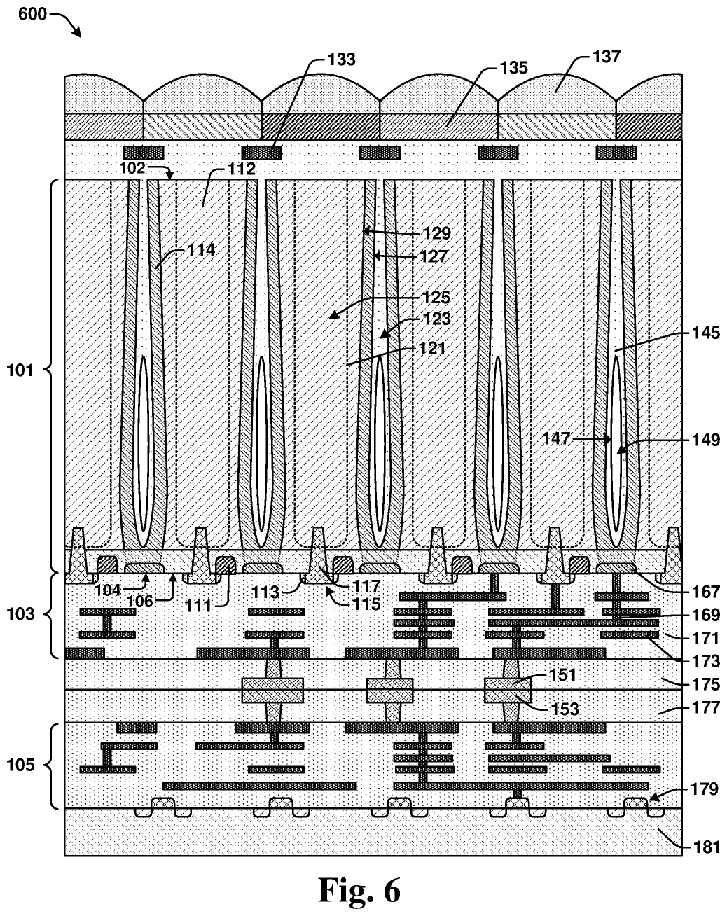

FIG. 6 illustrates a cross-sectional view of an image sensing device 600 according to some other embodiments. The image sensing device 600 is like the image sensing device 500 of FIG. 5 except that in the image sensing device 500 the floating diffusion regions 111 are laterally offset from the DTI structure 123. Without the front side epitaxial layer 165, it may be difficult to form the floating diffusion regions 111 directly beneath the DTI structure 123.

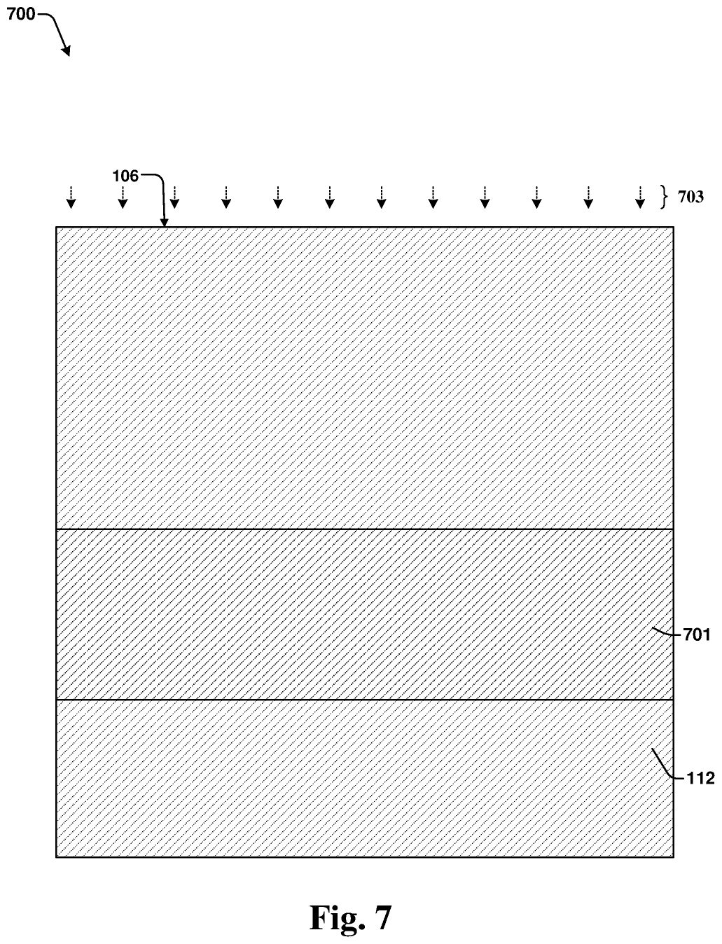

FIGS. 7-22 provide a series of cross-sectional views 700-2200 that illustrate an image sensing integrated circuit device according to the present disclosure at various stages of manufacture according to a process of the present disclosure. Although FIGS. 7-22 are described in relation to a series of acts, it will be appreciated that the order of the acts may in some cases be altered and that this series of acts are applicable to structures other than the ones illustrated. In some embodiments, some of these acts may be omitted in whole or in part. Furthermore, while FIGS. 7-22 are described in relation to a series of acts, it will be appreciated that the structures shown in FIGS. 7-22 are not limited to a method of manufacture but rather may stand alone as structures separate from the method.

As shown by the cross-sectional view 700 of FIG. 7, the method may begin with providing the bulk semiconductor 112 and implanting with n-type dopants 703 to form a deep n-well 701. The bulk semiconductor 112 be formed from a single crystal any may be any type of semiconductor, e.g., silicon (Si), a group III-V or some other binary semiconductor, a tertiary semiconductor (e.g., AlGaAs), a higher order semiconductor, or the like. In some embodiments, the bulk semiconductor 112 is or comprises silicon (Si) or the like.

In some embodiments, the implantation process is a blanket implant performed without a mask so that the deep n-well 701 extends across the bulk semiconductor 112. In some embodiments, the n-type dopants 703 are implanted with an energy in the range from about 2000 keV to about 10,000 keV. In some embodiments, the n-type dopants 703 are implanted with an energy in the range from about 3000 keV to about 6000 keV. In some embodiments, the n-type dopants 703 are implanted with a dosage in the range from about 1×10¹⁰ to about 1×10¹³ atoms/cm². In some embodiments, the deep n-well 701 has a peak dopant concentration at about 2 μm to about 5 μm below the front side 106. The deep n-well 701 may have a depth such that it will extend to the back side 102 (see FIG. 1A) after the bulk semiconductor 112 is thinned. Other dopant implantation processes related to the formation of photodiodes 121 (see FIG. 1A), including for example shallower n-well implants, may also be performed at this stage of processing, with or without masks.

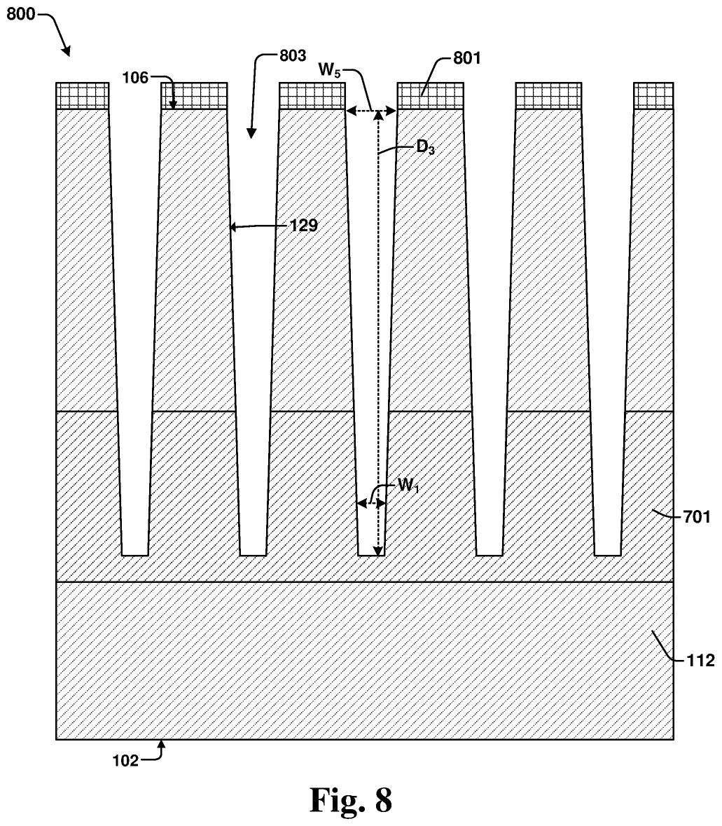

As shown by the cross-sectional view 800 of FIG. 8, a mask 801 may be formed and used to etch trenches 803 in the bulk semiconductor 112. The trenches 803 may be etched by any suitable process. In some embodiments, the etch process is a dry etch. In some embodiments, the etch process includes deep reactive ion etching (DRIE), or the like. In some embodiments, the etch process includes alternating steps of exposure to reactive ions and deposition of a passivation layer that limits lateral etching. The trenches 803 have the maximum width W₅ at or near the front side 106. The sidewalls 129 may be angled so that the trenches 803 decrease in width with increasing depth down to the width W₁. Keeping the sidewall 129 nearly vertical is desirable from the point of view of keeping the DTI structure 123 (see FIG. 1A) narrow, however, it is difficult to increase the verticality of the sidewalls 129 without increasing the energy of the ions used in the etch process. Increasing the energy of the ions increases damage to the bulk semiconductor 112, which can lead to dark currents, white pixels, and the like. Accordingly, in some embodiments a lower energy etch is employed. The lower energy etch is reflected by the greater angle of the sidewalls 129. In some embodiment, the sidewalls 129 are angled so that the width W₁ is less than or equal to 60% of the width W₅. In some embodiment, the sidewalls 129 are angled so that the width W₁ is less than or equal to 50% of the width W₅.

The trenches 803 have a depth D₃. In some embodiments, the depth D₃ is in the range from about 1.5 μm to about 5 μm. In some embodiments, the depth D₃ is in the range from about 2 μm to about 3 μm. In some embodiments, the trenches 803 have an aspect ratio in the range from about 10:1 to about 20:1. In some embodiments, the aspect ratio is in the range from about 13:1 to about 16:1.

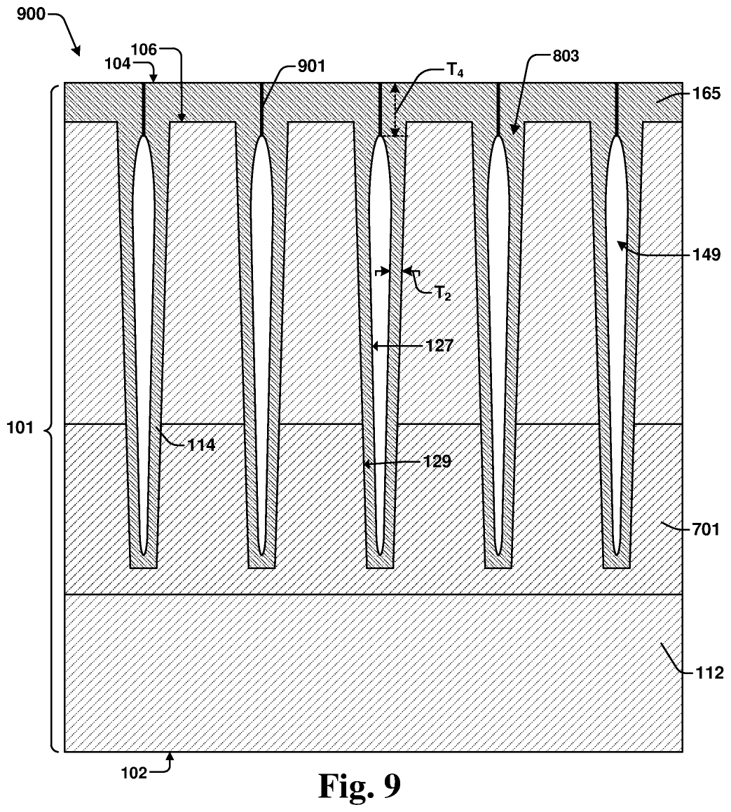

As shown by the cross-sectional view 900 of FIG. 9, the mask 801 may be stripped and the epitaxial layer 114 may be grown in the trenches 803 and on the front side 106. The epitaxial layer 114 may be any suitable semiconductor. In some embodiments, the epitaxial layer 114 is silicon or the like with p-type doping. The p-type dopant may be boron (B), arsenic (As), or the like. The epitaxial layer 114 merges with the bulk semiconductor 112 to form the semiconductor body 101 with the front side 104.

The conditions for the epitaxial growth process may include, for example, a temperature in the range from about 700° C. to about 1000° C. and a pressure in the range from about 10 to about 500 torr. The semiconductor source may be a hydride such as trichlorosilane (TCS), dichlorosilane (DCS), silane (SiH₄), the like, or some other suitable gas. The dopant source may also be a hydride such as diborane (B₂H₆), arsine (AsH₃), the like, or some other suitable gas. In some embodiments, the epitaxial layer 114 is formed with a dopant concentration in the range from about 1×10¹⁵ to about 1×10¹⁸ atoms/cm³. In some embodiments, the epitaxial layer 114 is formed with a dopant concentration in the range from about 1×10¹⁵ to about 2×10¹⁵ atoms/cm³. In some embodiments, the epitaxial layer 114 is formed with a resistivity in the range from about 0.1 to about 100 Ohm-cm. In some embodiments, the epitaxial layer 114 is formed with a resistivity in the range from about 8 to about 12 Ohm-cm.

The deposition conditions are selected so that the trenches 803 close near their entrances. This closure is desirable in terms of increasing the substrate area in which to semiconductor devices may be formed in the front side 104. The closure of the trenches 803 near their entrances is also desirable in terms of leaving the voids 149 to be lined with or filled with dielectric at a later stage of processing. In some embodiments, the epitaxial growth process is continued beyond the point of this closure in order to increase the thickness of the front side epitaxial layer 165. In some embodiments, the trenches 803 close within the first 40 nm to 100 nm of epitaxial growth. In some embodiments, the epitaxial growth is continued so as to increase the thickness of the front side epitaxial layer 165 by an amount in the range from about 50 nm to about 200 nm after the trenches 803 have closed.

In some embodiments, dislocations 901 form where growth from opposing sidewalls 129 of the trenches 803 begins to merge. It is desirable to keep these dislocations with a distance T₄ of the front side 104 so that these dislocations may be repaired by a laser annealing process or the like. In some embodiments, the distance T₄ is in the range from about 100 nm to about 400 nm. In some embodiments, the distance T₄ is in the range from about 200 nm to about 300 nm.

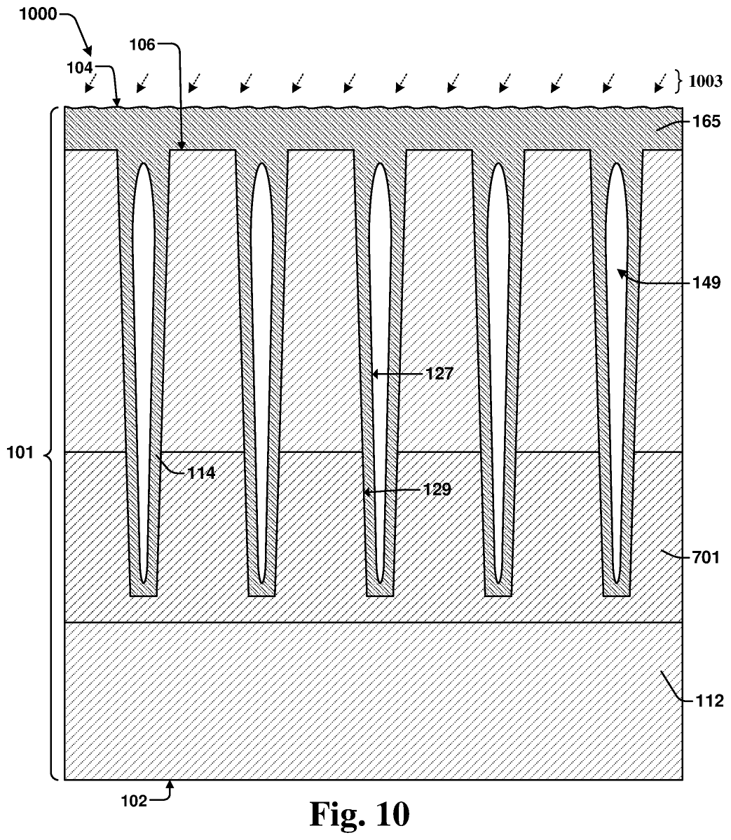

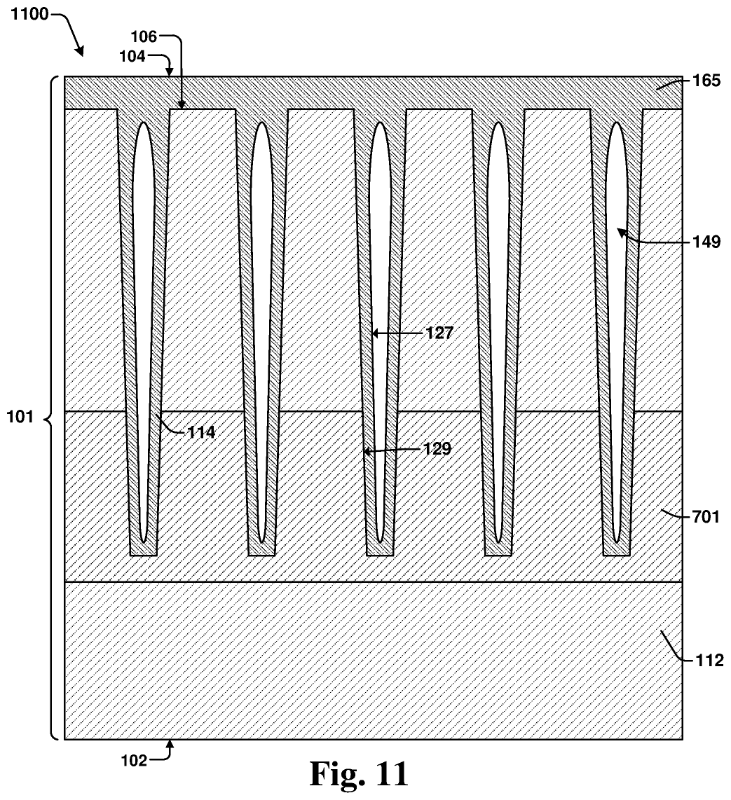

FIGS. 10 and 11 illustrate processing that may be used to remove or ameliorate the dislocations 901. In some embodiments, the dislocations 901 are avoided by a suitable selection of conditions for the epitaxial growth process or the dislocations 901 are eliminated as they form during the epitaxial growth process. For example, temperature cycling may be carried out in conjunction with the epitaxial growth process to provide in situ annealing. Accordingly, the processing of FIGS. 10 and 11 is optional.

As shown by the cross-sectional view 1000 of FIG. 10, an annealing process may be carried out to remove the dislocations 901. The annealing process may be rapid thermal annealing (RTA), furnace annealing, or laser annealing. In some embodiments, the annealing process is one that selectively heats an upper layer of the semiconductor body 101. In some embodiments, the annealing process is laser annealing or the like. In some embodiments, the annealing is carried out with pulsed ultraviolet laser light 1003 which may be provided by an excimer laser. For example, the annealing process may be conducted with a 248 nm wavelength KrF excimer laser or the like. In some embodiments, the laser pulses are from about 2 to about 100 ns, e.g., about 24 ns. In some embodiments, the laser light intensity is in the range from about 400 to about 1000 mJ/cm². In some embodiments, the intensity is at least about 700 mJ/cm². The annealing process may roughen the surface on the front side 104.

As shown by the cross-sectional view 1100 of FIG. 11, a planarization process may be carried out to smooth the surface on the front side 104. The planarization process may be CMP, the like, or some other suitable process. In some embodiments, the CMP process reduce a thickness of the front side epitaxial layer 165 by an amount in the range from about 20 nm to about 100 nm, e.g., about 50 nm.

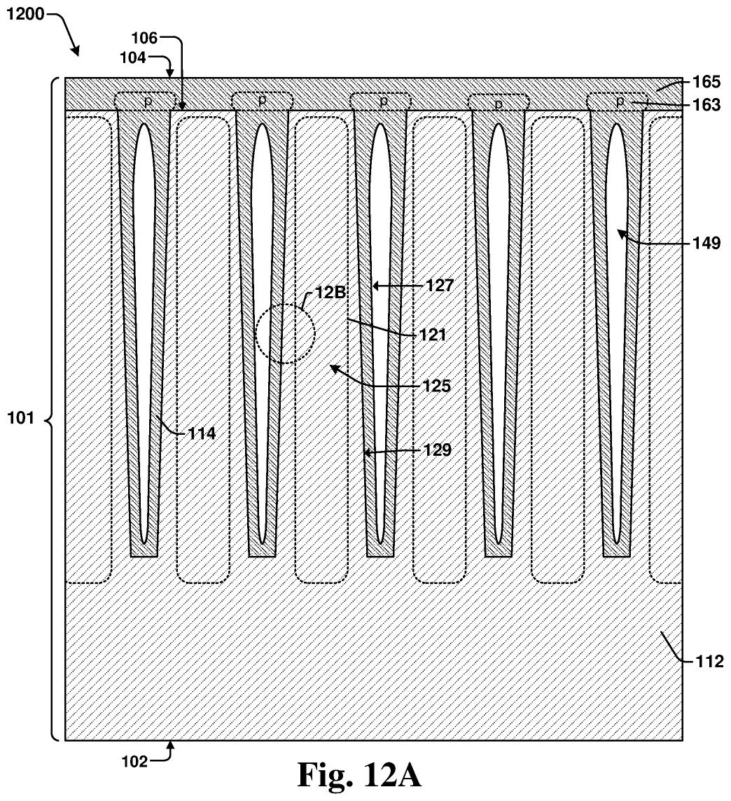

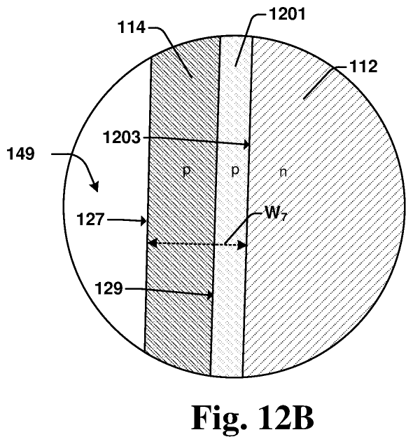

As shown by the cross-sectional view 1200 of FIG. 12A, additional doping may be carried out to complete the formation of the photodiodes 121 and, optionally, the shallow p-wells 163 (see FIG. 1). The doping processes may include masks (not shown). In some embodiments, at least part of the PN junction of the photodiodes 121, in particular the part that is furthest from the front side 104, has P-doping provided by the epitaxial layer 114. The p-type dopants may remain within the epitaxial layer 114 or diffuse slightly into the bulk semiconductor 112.

FIG. 12B is an expanded view of the of the area 12B in FIG. 12A and focuses on a PN junction 1203 formed between the p-type dopants of the epitaxial layer 114 and a region of the bulk semiconductor 112 that has n-type doping. As illustrated, there may be a region 1201 in which the bulk semiconductor 112 has become p-doped as a result of diffusion of p-type dopants from the epitaxial layer 114. When the p-type doping is provided exclusively by the epitaxial layer 114, the width W₇ of the zone between the sidewall 127 and the PN junction 1203 is kept narrow. Keeping the width W₇ small increases the full well capacity of the resulting photodiodes 121 (see FIG. 1A). In some embodiments, the thickness W₇ is in the range from about 30 nm to about 110 nm. In some embodiments, the thickness W₇ is about 80 nm or less.

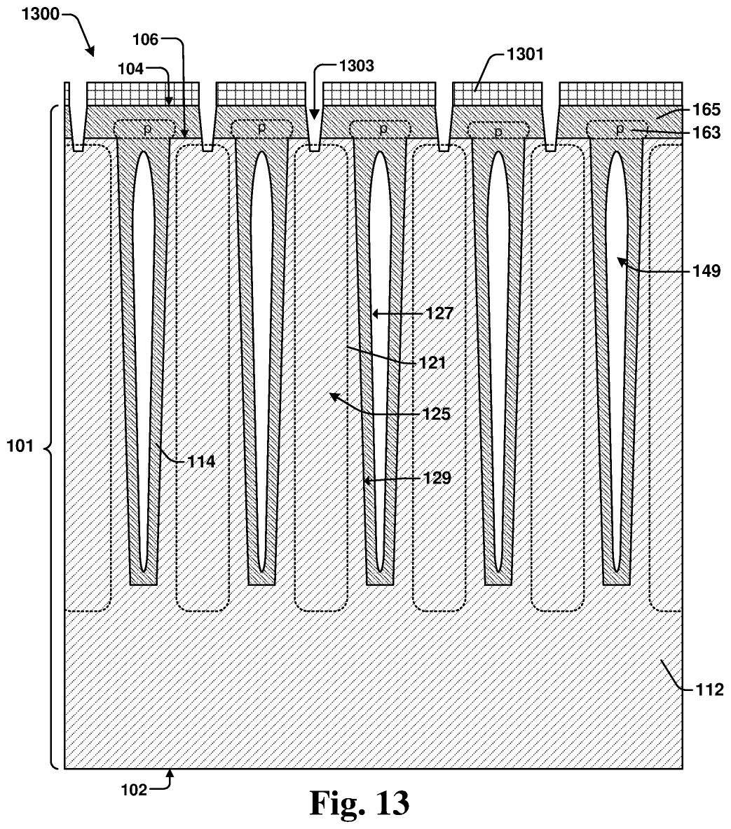

As shown by the cross-sectional view 1300 of FIG. 13, a mask 1301 may be formed and used to etch trenches 1303 in the front side 104. The trenches 1303 extend through the front side epitaxial layer 165 and into the bulk semiconductor 112. After the etch process, the mask 1301 is stripped.

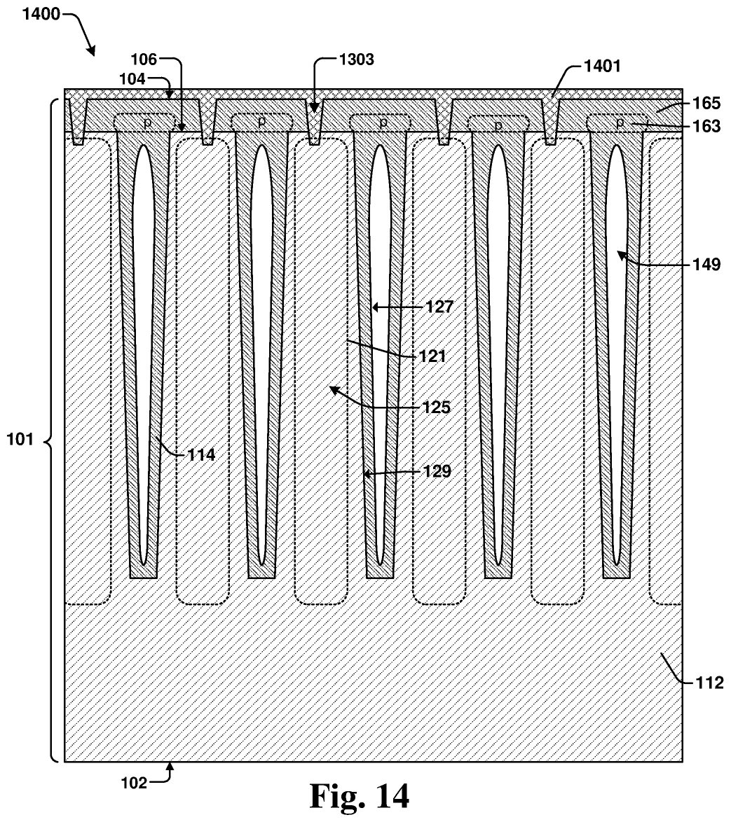

As shown by the cross-sectional view 1400 of FIG. 14, a gate stack 1401 is formed so as to line and then fill the trenches 1303. The gate stack 1401 includes a gate dielectric layer and a gate electrode layer. The gate dielectric layer may be or comprise an oxide, a high K dielectric, or the like. The gate dielectric layer may be formed by oxidation, deposition, or the like. The gate electrode layer may be polysilicon, a metal, or the like and is formed by deposition. The deposition processes may be or include atomic layer deposition (ALD), chemical vapor deposition (CVD), or physical vapor deposition (PVD).

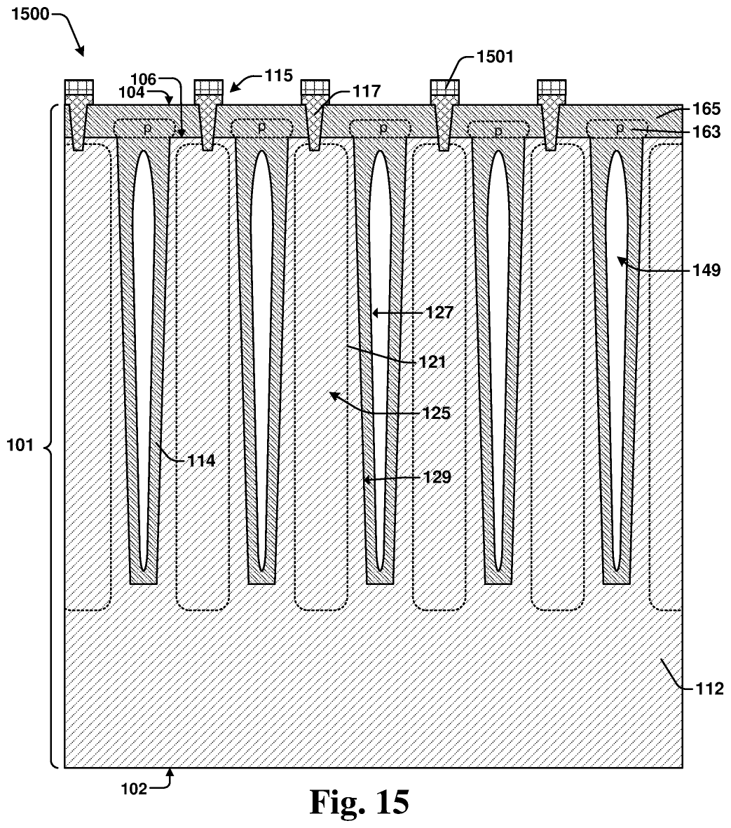

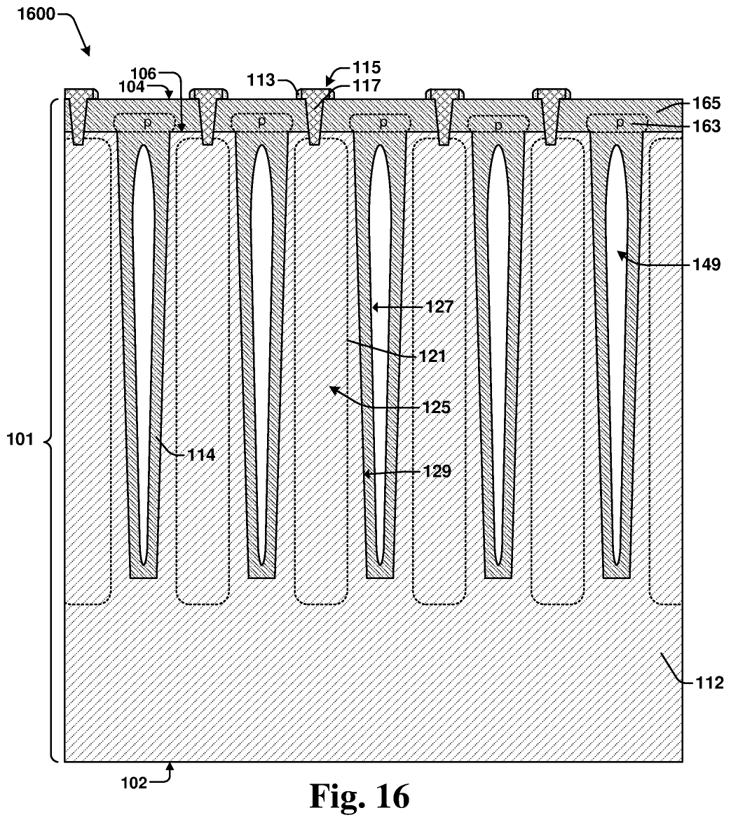

As shown by the cross-sectional view 1500 of FIG. 15, a mask 1501 may be formed and used to pattern the gate stack 1401 so as to define transfer gates 115 or the like. As shown by the cross-sectional view 1600 of FIG. 16, the mask 1501 may be stripped and spacers 113 may be formed. The spacers 113 may include one or more layers of oxides, nitrides, oxycarbides, oxynitrides, the like, or any other suitable materials. The spacers 113 may be formed by deposition of the spacer material followed by etching.

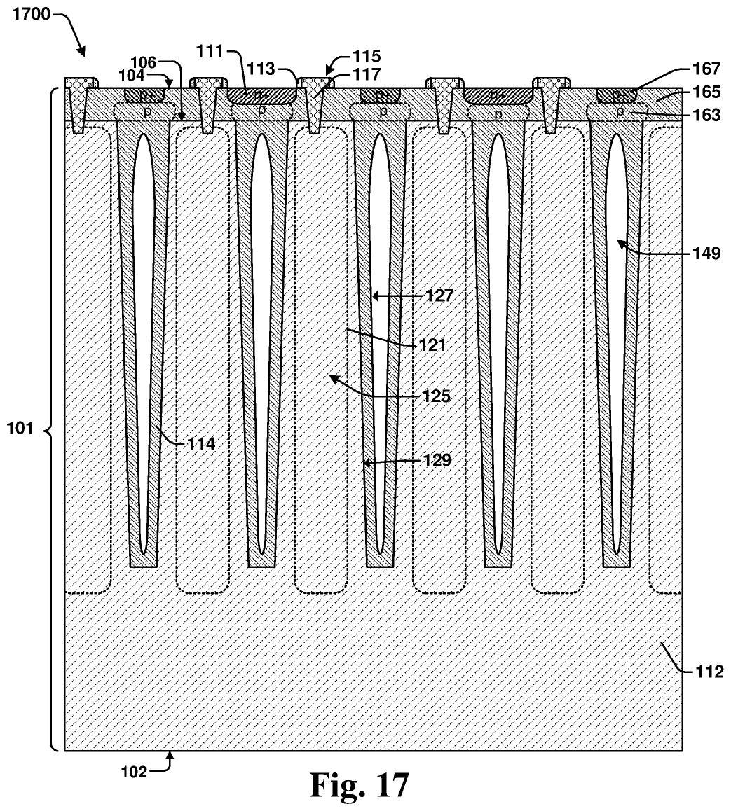

As shown by the cross-sectional view 1700 of FIG. 17, the heavily p-doped contact regions 167 and the floating diffusion regions 111 may be formed. These regions may be formed by masking and ion implantation. The ion implantation for the floating diffusion regions 111 is at least partially masked by the spacers 113 so that the floating diffusion regions 111 have sides that are aligned to the spacers 113. In some embodiments, the floating diffusion regions 111 are formed directly over trenches defined by the sidewalls 129 and lined with the epitaxial layer 114 (see FIG. 1C). In some embodiments, the floating diffusion regions 111 are formed in the front side epitaxial layer 165. In some embodiments, the heavily p-doped contact regions 167 are formed directly over trenches defined by the sidewalls 129 and lined with the epitaxial layer 114. In some embodiments, the heavily p-doped contact regions 167 are formed in the front side epitaxial layer 165. This processing completes the formation of the photodetectors 125 within the semiconductor body 101.

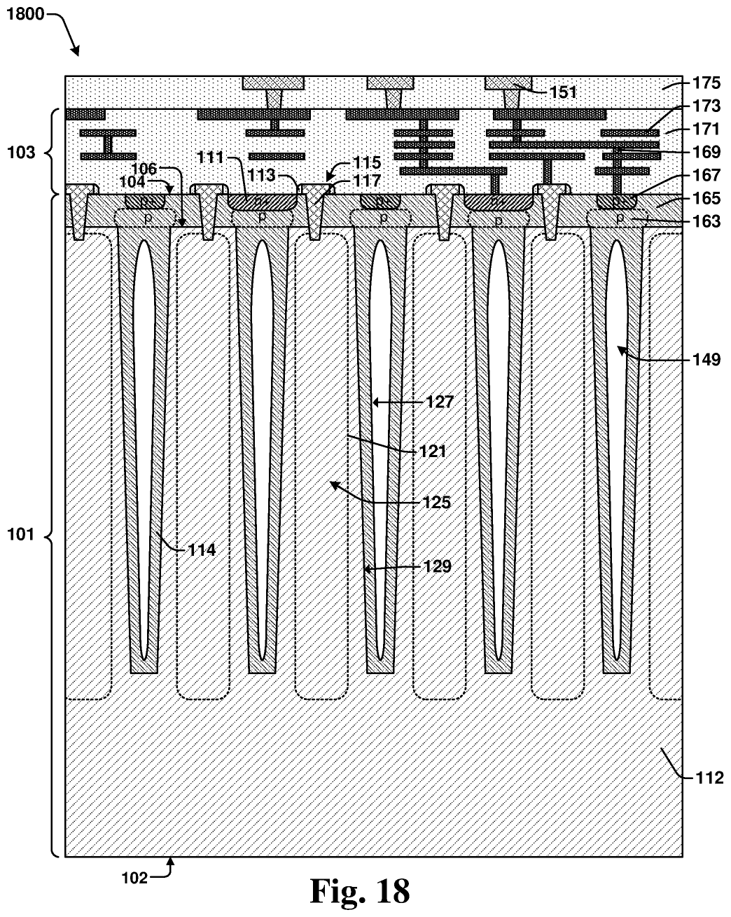

As shown by the cross-sectional view 1800 of FIG. 18, the front side metal interconnect structure 103 and the first bonding layer 175 may be formed over the front side 104. These structures may be formed by damascene processes or the like (e.g., a single damascene process or a dual damascene process). A damascene process may include forming a layer of the interlevel dielectric 171, etching the layer to form a via hole and/or a trench, and filling the via hole and/or trench with a conductive material to form wires 173 or vias 169. The layers of interlevel dielectric 171 may be formed by ALD, CVD, PVD, the like, or any other suitable process. The conductive material may be deposited by ALD, CVD, PVD, electroplating, electro-less plating, the like, or any other suitable process. The interlevel dielectric 171 may be silicon dioxide (SiO₂), a low k dielectric, or the like. The conductive material may be or comprise tungsten, copper, aluminum, or the like. The first bonding layer 175 may be formed by similar processing.

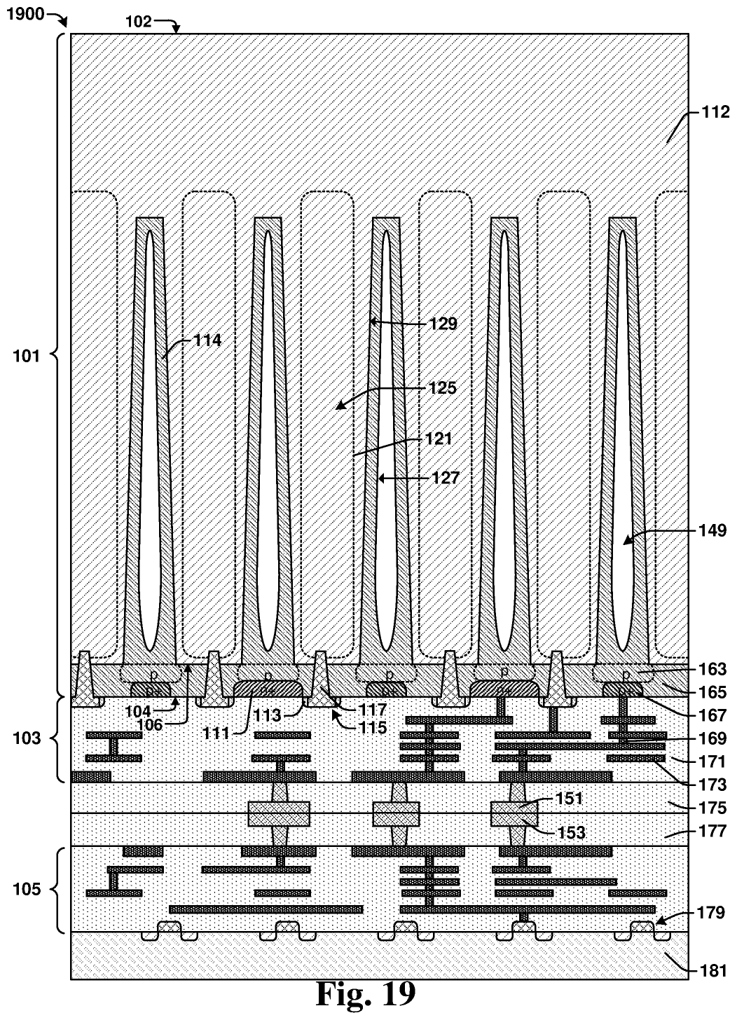

As shown by the cross-sectional view 1900 of FIG. 19, the semiconductor body 101 may be flipped over and bonded to a second substrate 181. A second metal interconnect structure 105 and a second bonding layer 177 may be disposed over the second substrate 181. In some embodiments, the second substrate 181 is a support substrate or a handle substrate. In some embodiments, the second substrate 181 comprises a semiconductor material, such as silicon, and semiconductor devices 179 such as transistors or the like are formed on the second substrate 181. The semiconductor body 101 may be bonded to the second substrate 181 via the first bonding layer 175 and the second bonding layer 177. The bonding process may be hybrid bonding, the like, or some other suitable bonding process. In some embodiments, the first bonding layer 175 and the second bonding layer 177 form electrical connections between the semiconductor body 101 and the second substrate 181.

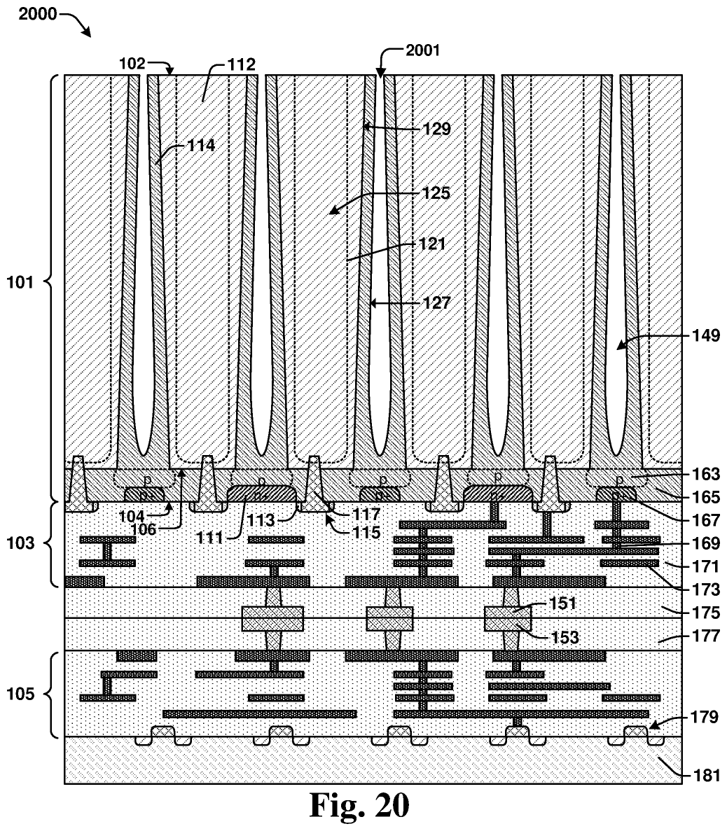

As shown by the cross-sectional view 2000 of FIG. 20, after bonding, the semiconductor body 101 may be thinned from the back side 102. Thinning the semiconductor body 101 allows light to pass more easily to the photodetectors 125. In some embodiments, the thinning process forms opening 2001 into the trenches defined by the sidewalls 127. The semiconductor body 101 may be thinned by etching, mechanical grinding, CMP, the like, or any other suitable process. In some embodiments, the semiconductor body 101 is thinned to less than about 5 μm. In some embodiments, the semiconductor body 101 is thinned to about 3 μm or less.

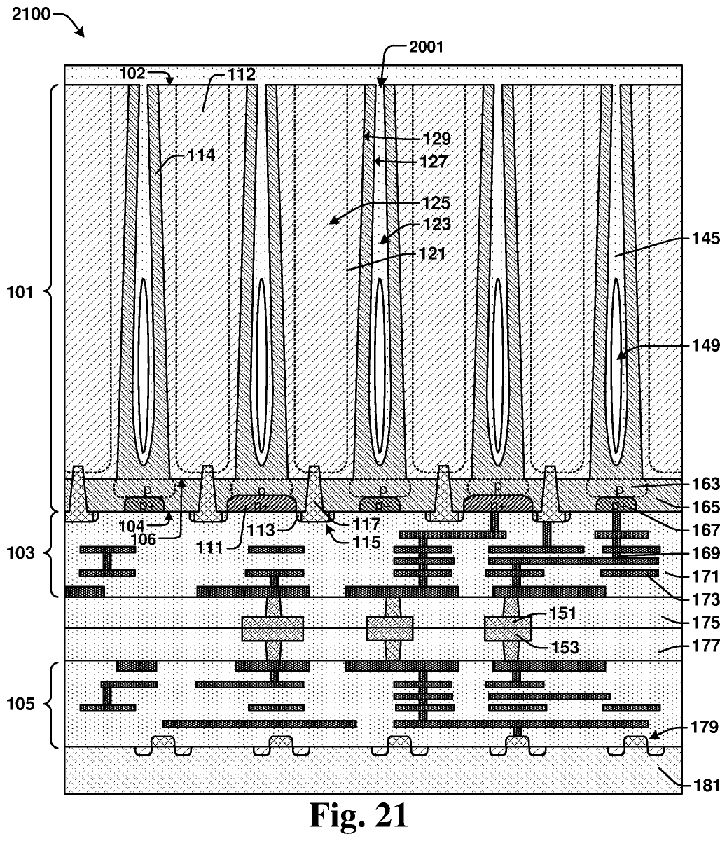

As shown by the cross-sectional view 2100 of FIG. 21, the isolation dielectric 145 may be deposited so as to line the sidewalls 127 provided by the epitaxial layer 114. The isolation dielectric 145 may also be deposited on the back side 102. The isolation dielectric 145 may include one or more layers of suitable dielectrics. In some embodiments, at least a base layer of the isolation dielectric 145 is a high-κ dielectric deposited with a conformal deposition process such as ALD or the like. Examples of high-κ dielectrics that may be suitable include hafnium oxide (HfO), aluminum oxide (AlO), zirconium oxide (ZrO), titanium oxide (TiO), strontium oxide (SrO), barium oxide (BaO), barium titanate (BaTiO₃), tantalum oxide (Ta₂O₃), lanthanum oxide (La₂O₃), yttrium oxide (Y₂O₃), and the like. In some embodiments, the base layer is hafnium oxide (HfO), aluminum oxide (AlO), or the like. Additional layers may be deposited with non-conformal deposition processes so that the isolation dielectric 145 is thicker on the back side 102 than on the sidewalls 127. The deposition processes may include ALD, PVD, CVD, the like, or any other suitable process. In some embodiments, the additional layers include tantalum oxide (Ta₂O₃) or the like. In some embodiments, the total thickness of the isolation dielectric 145 on the sidewalls 127 is in the range from about 10 nm to about 100 nm.

In some embodiments, the total thickness of the isolation dielectric 145 on the back side 102 is in the range from about 50 nm to about 500 nm at the time the openings 2001 become sealed. In some embodiments, the openings 2001 become sealed while voids 149 remain. Additional layers may be added to the isolation dielectric 145. These additional layers may include, for example, layers of silicon dioxide (SiO₂) or the like. In some embodiments, a layer of tantalum oxide or the like is formed on the back side 102 before any layers of silicon dioxide. Tantalum oxide has a refractive index intermediate between silicon dioxide and silicon. Having a layer or tantalum oxide between the bulk semiconductor 112 and any silicon dioxide layers formed over the back side 102 may reduce reflections.

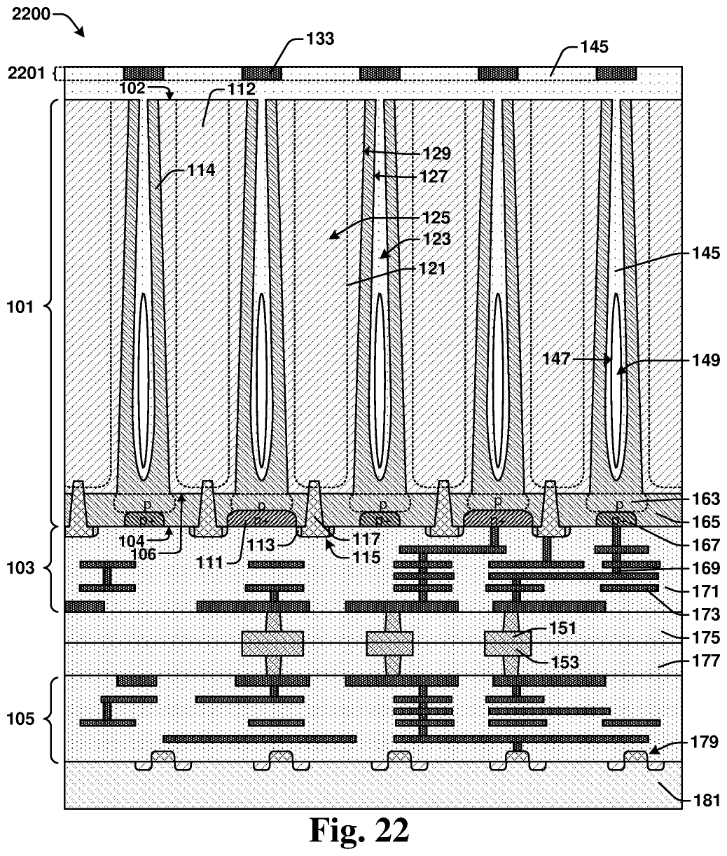

As shown by the cross-sectional view 2200 of FIG. 22, an additional layer 2201 may be added to the isolation dielectric 145 and a back side metal grid 133 formed. The back side metal grid 133 may be formed by etching trenches in the additional layer 2201 and filling the trenches with metal. The back side metal grid 133 may reduce crosstalk between adjacent photodetectors 125. Color filters 135 and microlenses 137 may be formed over the structure shown by the cross-sectional view 2200 of FIG. 22 to produce the image sensing device 100 of FIG. 1A.

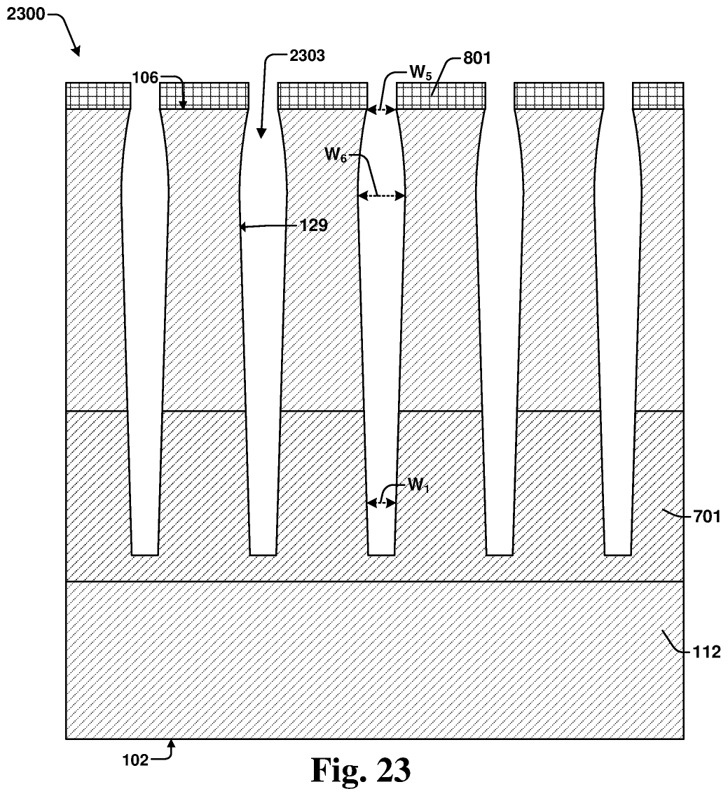

The cross-sectional view 2300 of FIG. 23 illustrates a variation of the foregoing process that may be used to produce the image sensing device 200 of FIG. 2A. The variation relates to a shift from the etch process used to form the trenches 803 as shown in the cross-sectional view 800 of FIG. 8. The shift results in the trenches 2303, which have the maximum width W₆ a distance below the front side 106. The change in process conditions may relate to the power and pressure of a DRIE process, particularly the part that forms the upper parts of the trenches 2303. The etching power may be kept relatively low. In some embodiments, the etch power is sufficiently low that the etch rate is kept below 2 m/min. In some embodiments, the etch power is sufficiently low that the etch rate is about 1 m/min or less. The pressure may also be kept relatively low. In some embodiments, the pressure is in the range from about 1 to about 100 millitorr. In some embodiments, the pressure is in the range from about 3 to about 30 millitorr. In some embodiments, the pressure is in the range from about 5 to about 20 millitorr. Varying the power and the pressure controls the shape of the trenches 2303. After the trenches 2303 are formed, the process may continue as shown and described in connection with the cross-sectional views 900-2200 of FIGS. 9-22 to produce the image sensing device 200 of FIG. 2A.

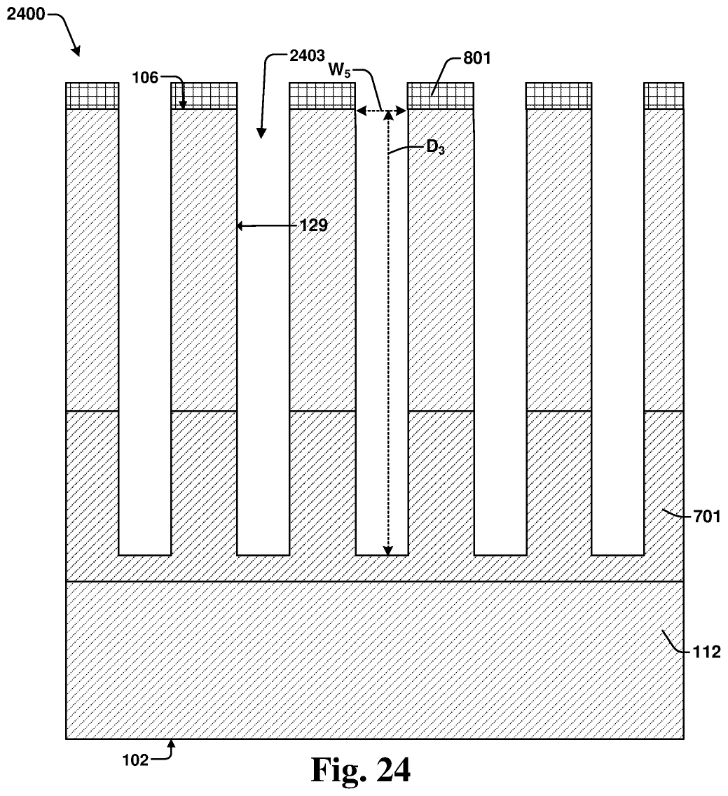

The cross-sectional view 2400 of FIG. 24 illustrates another variation of the process of FIGS. 7-22 that may be used to produce the image sensing device 400 of FIG. 4A. This variation also relates to a change from the etch process used to form the trenches 803 shown in the cross-sectional view 800 of FIG. 8. In this variation, the etch power is increased to provide the trenches 2403. The sidewalls 129 of the trenches 2403 are substantially vertical. After the trenches 2403 are formed, the process may continue as shown and described in connection with the cross-sectional views 900-2200 of FIGS. 9-22 to produce the image sensing device 400 of FIG. 4A.

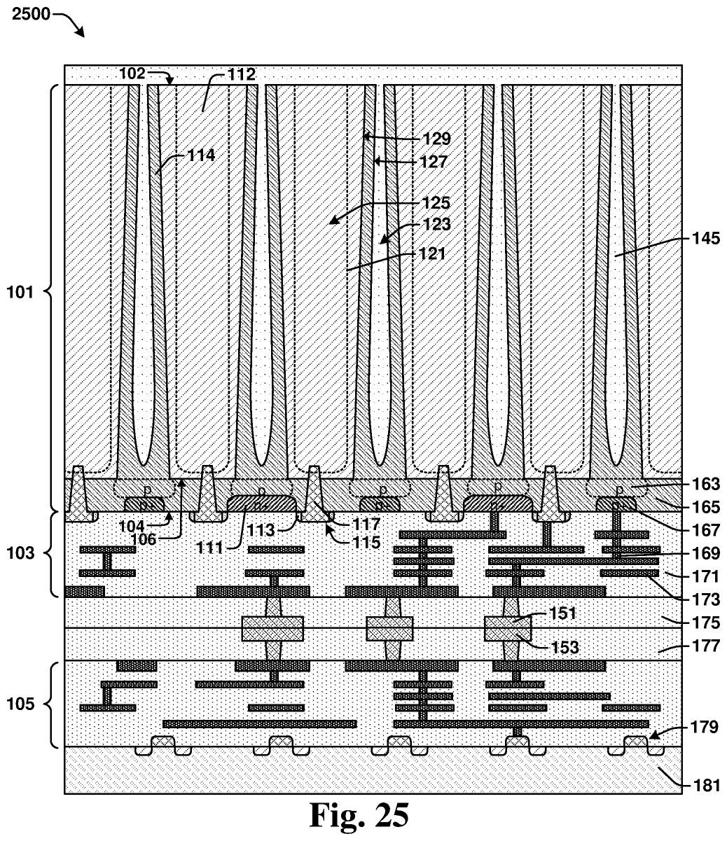

The cross-sectional view 2500 of FIG. 25 illustrates a variation of the process of FIGS. 7-22 that may be used to produce the image sensing device 300 of FIG. 3. The variation relates to a change in the process used to deposit the isolation dielectric 145 in the openings 2001 (see FIG. 20). The change results in the isolation dielectric 145 filling in the trenches defined by the sidewalls 127 of the epitaxial layer 114 so that the DTI structure 123 is formed without the voids 149 (see FIG. 20). In some embodiments, the process of depositing the isolation dielectric 145 to form the DTI structure 123 without voids includes a flowable CVD process. In some embodiments, a first part of the deposition process is ALD or the like and the last part of the deposition process is a flowable CVD. In some embodiments, all of the isolation dielectric 145 that forms the DTI structure 123 is deposited by a flowable CVD process. The flowable CVD processes includes applying a liquid to the back side 102, causing the liquid to flow into the gaps with the semiconductor body 101, and curing to solidify the liquid so as to produce a gap-filling dielectric that is substantially free of voids. Dielectrics that may be deposited by a flowable CVD process include, without limitation, silicon dioxide (SiO₂), silicon nitride (Si₃N₄), aluminum oxide (Al₂O₃), hafnium oxide (HfO₂), and the like. Forming the trenches 2403 as shown by the cross-sectional view 2400 of FIG. 24 facilitates forming the DTI structure 123 without the voids 149 (see FIG. 20) regardless of which process is used to deposit the isolation dielectric 145.

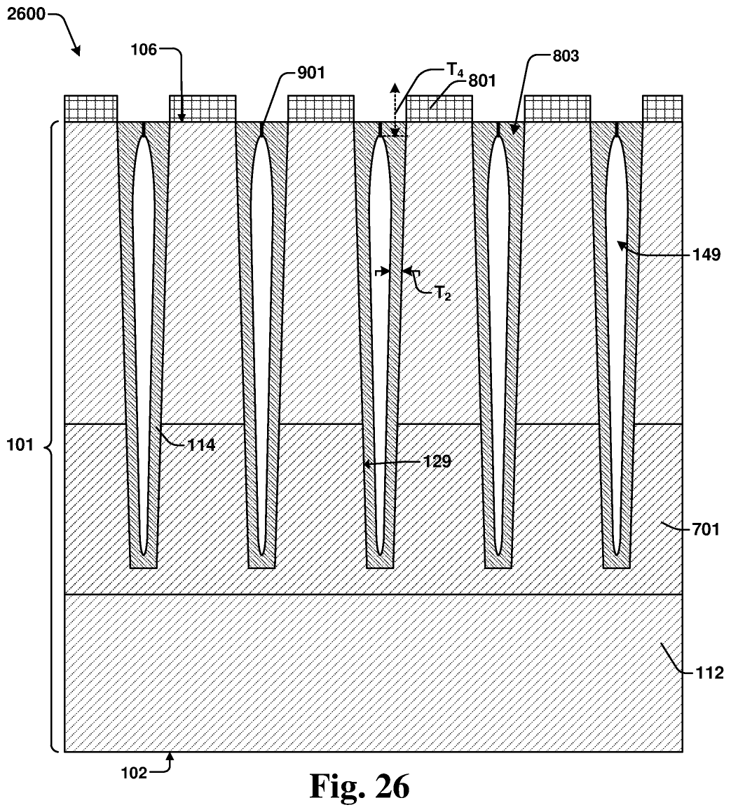

The cross-sectional view 2600 of FIG. 26 illustrates a variation of the process of FIGS. 7-22 that may be used to produce the image sensing device 500 of FIG. 5. The variation relates to a difference in the way the epitaxial layer 114 is formed. In the process illustrated by the cross-sectional view 900 of FIG. 9, the epitaxial layer 114 is grown by a non-selective growth process, i.e., one in which there is no mask on the front side 106 so that the front side epitaxial layer 165 is produced. The process illustrated by the cross-sectional view 2600 of FIG. 26 is a selective epitaxial growth process, i.e., one in which the epitaxial layer 114 is grown while the mask 801 remains on the front side 106 preventing the formation of the front side epitaxial layer 165. Processing may continue as shown in the cross-sectional views 1000-2200 of FIGS. 10-22 with an additional doping step to produce the p-doped layer 501 in the front side 106 (see FIG. 5).

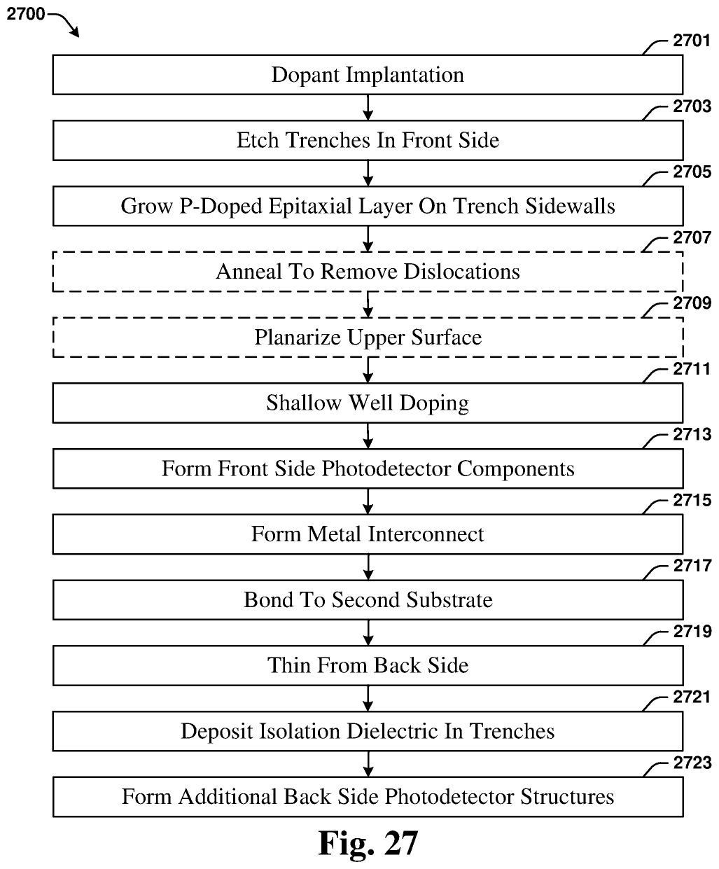

FIG. 27 provides a flow diagram for a method 2700 of forming an image sensing device according to some embodiments. While the method 2700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2700 may begin with act 2701, performing one or more dopant implantations. In some embodiments, at least one of these dopant implantations is a blanket implant of n-type dopants as illustrated by the cross-sectional view 700 of FIG. 7. This doping may provide n-type regions that later combine with epitaxially grown p-type semiconductor to form PN junctions for photodiodes with narrow regions of p-type doping as shown in FIG. 12B.

Act 2703 is forming trenches in the semiconductor substrate. In some embodiments, these trenches are formed with a relatively low energy so that the trenches have sloped sidewalls, but relatively low substrate damage. The cross-sectional view 800 of FIG. 8 provides an example. In some embodiments, these trenches are formed with higher energy etching. The higher energy etching causes more substrate damage but produces more vertical sidewalls. The cross-sectional view 2400 of FIG. 24 provides an example. In some embodiments, these trenches are formed with a process that causes the trenches to widen below the trench mouths. The cross-sectional view 2300 of FIG. 23 provides an example.

Act 2705 is growing an epitaxial layer of p-doped semiconductor on the trench sidewalls. The p-doped epitaxial layer reduces the aspect ratio of the trenches. In some embodiments, the p-doped epitaxial layer is formed by a non-selective growth process. The cross-sectional view 900 of FIG. 9 provides an example. In some embodiments, the p-doped epitaxial layer is formed by a selective growth process. The cross-sectional view 2600 of FIG. 26 provides an example. In some embodiments, the epitaxial growth seals off the trench mouths. In some embodiments, dislocations are formed where epitaxial growths from opposing sides of the trenches meet.

Act 2707 is an optional step that may be performed if formation of the dislocations is not avoided or ameliorated during the epitaxial growth process. Act 2707 is annealing. In seme embodiments, the annealing process is laser annealing. The cross-sectional view 1000 of FIG. 10 provides an example.

Act 2709 is an optional step of planarizing the epitaxial growth on the front side of the substrate. Planarization may be used to remove surface roughness caused by the annealing process or just surface roughness left by the epitaxial growth process. The cross-sectional view 1100 of FIG. 11 provides an example.

Act 2711 is shallow well doping. This doping may complete the formation of photodiodes. In some embodiments, this step includes formation of shallow p-wells in a front side epitaxial layer produced by the epitaxial growth process of act 2705. The cross-sectional view 1200 of FIG. 12A provides an example. In some embodiments, these shallow p-wells facilitate forming contacts for grounding the epitaxial layer. In some embodiments, these shallow p-wells provide isolation for floating diffusion regions that will be formed subsequently.

Act 2713 is forming front side photodetector components. These components may include, for example, transfer gates and floating diffusion regions. The cross-sectional views 1300-1700 of FIGS. 13-17 provide an example.

Act 2715 is forming a metal interconnect structure on the front side. The cross-sectional view 1800 of FIG. 18 provides an example. Act 2717 is bonding to a separate substrate. The cross-sectional view 1900 of FIG. 19 provides an example.

Act 2719 is thinning the substrate from the back side. In some embodiments, the thinning process creates openings into the trenches produced by act 2703 and narrowed by act 2705. The cross-sectional view 2000 of FIG. 20 provides an example.

Act 2721 is depositing an isolation dielectric in the trenches so as to produce a DTI structure within the trenches. In some embodiments, this process is carried out in a manner that leaves voids in the trenches. The cross-sectional view 2100 of FIG. 21 provides an example. In some embodiments, this process is carried out in a manner that fills the trenches while eliminating voids. The cross-sectional view 2500 of FIG. 25 provides an example.

Act 2723 is forming back side photodetector structures. These additional structures may include a back side metal grid, color filters, microlenses, and the like. The cross-sectional view 2200 of FIG. 22 provides an example of forming the back side metal grid. The image sensing device 100 of FIG. 1A provides an example of the color filters and microlenses.

Some aspects of the present disclosure relate to an image sensing device having photodetectors a the semiconductor body. A deep trench isolation structure extends into the semiconductor body to laterally surround the photodetectors. The semiconductor body includes an epitaxial layer of p-doped semiconductor that lines the deep trench isolation structure. In some embodiments, the epitaxial layer of p-doped semiconductor extends from the front side to the back side. In some embodiments, the deep trench isolation structure extends from the back side but is spaced apart from the front side. In some embodiments, the deep trench isolation structure is widest within the semiconductor body at point that is between the front side and the back side. In some embodiments, the epitaxial layer of p-doped semiconductor has a width that is constant or becomes progressively narrower from the front side to the back side. In some embodiments, the epitaxial layer extends over the front side.

Some aspects of the present disclosure relate to an image sensing element arranged within the substrate. P-doped semiconductor on sidewalls of the substrate form one or more trenches on opposing sides of the image sensing element. The trenches become progressively wider with increasing distance from the first side in a first zone that is proximate the first side. The trenches become progressively wider with increasing distance from the second side in a second zone that is proximate the second side. In some embodiments, the first zone and the second zone meet. In some embodiments, the first zone and the second zone together extend from tops of the trenches to bottoms of the trenches. In some embodiments, the one or more trenches are filled with dielectric.

Some aspects of the present disclosure relate to a method of manufacturing an image sensing device. The method includes providing a semiconductor body, etching a grid of trenches in the front side of the semiconductor body, and epitaxially growing p-doped semiconductor in the trenches. An array of photodiodes is formed in the semiconductor body. The photodiodes are laterally separated by the trenches. In some embodiments, the epitaxial layer is annealed the front side of the semiconductor body. In some embodiments, the annealing comprises laser annealing. In some embodiments, the method further comprised chemical mechanical polishing the front side. In some embodiments, epitaxially growing the p-doped semiconductor in the trenches seals the trenches. In some embodiments, the semiconductor is thinned from the back side after which dielectric is deposited in the trenches from the back side. In some embodiments, the process of epitaxially growing the p-doped semiconductor in the trenches also epitaxially grows the p-doped semiconductor on the front side to provide a front side epitaxial layer. In some embodiments, floating diffusion region are formed in the front side epitaxial layer. In some embodiments, a deep n-well is implanted in the semiconductor body prior to etching the trenches. In some embodiments, the photodiodes include a PN junction formed by the p-doped semiconductor grown in the trenches together with the deep n-well. In some embodiments, the process of etching the trenches in the front side provides the trenches with greater widths within the semiconductor body than at the front side.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensing device, comprising:
a semiconductor body having a front side and a back side;
photodetectors within the semiconductor body;
a deep trench isolation structure extending into the semiconductor body to laterally surround the photodetectors; and
an epitaxial layer of p-doped semiconductor lining the deep trench isolation structure.

2. The image sensing device of claim 1, wherein the epitaxial layer of p-doped semiconductor extends from the front side to the back side.

3. The image sensing device of claim 1, wherein the deep trench isolation structure is widest within a the semiconductor body at point that is between the front side and the back side.

4. The image sensing device of claim 3, wherein the epitaxial layer of p-doped semiconductor has a width that is constant or becomes progressively narrower from the front side to the back side.

5. The image sensing device of claim 4, wherein the deep trench isolation structure is spaced apart from the front side.

6. The image sensing device of claim 1, wherein the epitaxial layer extends over the front side.

7. An image sensing device, comprising:
a substrate having a first side and a second side; and
an image sensing element arranged within the substrate, wherein p-doped semiconductor on sidewalls of the substrate form one or more trenches on opposing sides of the image sensing element;
wherein the trenches become progressively wider with increasing distance from the first side in a first zone that is proximate the first side; and
the trenches become progressively wider with increasing distance from the second side in a second zone that is proximate the second side.

8. The image sensing device of claim 7, wherein the first zone and the second zone meet.

9. The image sensing device of claim 7, wherein the first zone and the second zone together extend from tops of the trenches to bottoms of the trenches.

10. The image sensing device of claim 7, wherein the one or more trenches are filled with dielectric.

11. A method of manufacturing an image sensing device, the method comprising:
providing a semiconductor body having a front side and a back side;
etching trenches in the front side, wherein the trenches form a grid;
epitaxially growing p-doped semiconductor in the trenches; and
forming an array of photodiodes in the semiconductor body, wherein the photodiodes are laterally separated by the trenches.

12. The method of claim 11, further comprising annealing the front side of the semiconductor body after epitaxially growing the p-doped semiconductor in the trenches.

13. The method of claim 12, wherein the annealing comprises laser annealing.

14. The method of claim 13, further comprising chemical mechanical polishing the front side after annealing.

15. The method of claim 11, wherein epitaxially growing the p-doped semiconductor in the trenches seals the trenches.

16. The method of claim 11, further comprising:
thinning the semiconductor body from the back side; and
depositing dielectric in the trenches from the back side.

17. The method of claim 11, wherein epitaxially growing the p-doped semiconductor in the trenches further comprises epitaxially growing the p-doped semiconductor on the front side to provide a front side epitaxial layer.

18. The method of claim 17, further comprising forming a floating diffusion region in the front side epitaxial layer.

19. The method of claim 11, further comprising implanting a deep n-well in the semiconductor body prior to etching the trenches, wherein the p-doped semiconductor grown in the trenches together with the deep n-well form a PN junction of the photodiodes.

20. The method of claim 11, wherein etching the trenches in the front side provides the trenches with greater widths within the semiconductor body than at the front side.
